(19) United States
(12) Patent Application Publication
(10) Pub. No.: US 2013/0217231 A1
(43) Pub. Date: Aug. 22, 2013

(54) CHEMICAL MECHANICAL POLISHING (CMP) COMPOSITION

(71) Applicants: Bettina Drescher, Ludwigshafen (DE); Bastian Marten Noller, Lorsch (DE); Christine Schmitt, Mannheim (DE); Albert Budiman Sugiharto, Mannheim (DE); Yuzhuo Li, Mannheim (DE)

(72) Inventors: Bettina Drescher, Ludwigshafen (DE); Bastian Marten Noller, Lorsch (DE); Christine Schmitt, Mannheim (DE); Albert Budiman Sugiharto, Mannheim (DE); Yuzhuo Li, Mannheim (DE)

(73) Assignee: BASF SE, Ludwigshafen (DE)

(21) Appl. No.: 13/877,798

(22) PCT Filed: Oct. 4, 2011
(86) PCT No.: PCT/IB2011/054355

§ 371 Date: Apr. 4, 2013

Related U.S. Application Data
(60) Provisional application No. 61/389,739, filed on Oct. 5, 2010.

(30) Foreign Application Priority Data
Oct. 5, 2010 (EP) 10186601.0

(51) Int. Cl. C09K 13/04; H01L 21/306; C09K 13/06

(52) U.S. Cl. CPC C09K 13/04; C09K 13/06; H01L 21/30625
USPC 438/693; 252/79.2; 252/79.4

(57) ABSTRACT

A chemical mechanical polishing (CMP) composition Abstract Use of a chemical mechanical polishing (CMP) composition comprising (A) inorganic particles, organic particles, or a mixture thereof, (B) a heteropolyacid or a salt thereof, (C) a salt comprising chloride, fluoride, bromide, or a mixture thereof as anion, and (D) an aqueous medium, for polishing a substrate comprising a self-passivating metal, germanium, nickel phosphorous (NiP), or a mixture thereof.

This invention essentially relates to a chemical mechanical polishing (CMP) composition and its use in polishing substrates of the semiconductor industry. The CMP composition according to the invention comprises a heteropolyacid and a salt comprising chloride, fluoride, bromide, or a mixture thereof as anion and shows an improved polishing performance.

In the semiconductor industry, chemical mechanical polishing (abbreviated as CMP) is a well-known technology applied in fabricating advanced photonic, microelectromechanical, and microelectronic materials and devices, such as semiconductor wafers.

During the fabrication of materials and devices used in the semiconductor industry, CMP is employed to planarize metal and/or oxide surfaces. CMP utilizes the interplay of chemical and mechanical action to achieve the planarity of the to-be-polished surfaces. Chemical action is provided by a chemical composition, also referred to as CMP slurry or CMP composition. Mechanical action is usually carried out by a polishing pad which is typically pressed onto the to-be-polished surface and mounted on a moving platen. The movement of the platen is usually linear, rotational or orbital.

In a typical CMP process step, a rotating wafer holder brings the to-be-polished wafer in contact with a polishing pad. The CMP slurry or CMP composition is usually applied between the to-be-polished wafer and the polishing pad.

In the state of the art, CMP compositions comprising a heteropolyacid are known and described, for instance, in the following references.

U.S. Pat. No. 6,527,818 B2 discloses an aqueous dispersion for CMP comprising an abrasive, water and a heteropolyacid. This dispersion was described for the CMP of tungsten substrates.

JP-A-2005-223257 discloses an aqueous dispersion for CMP comprising a heteropoly-acid, an anionic surfactant, polishing particles (abrasive), and water. This dispersion was particularly appropriate for the CMP of copper substrates.

One of the objects of the present invention was to provide a CMP composition which is particularly appropriate and adopted for the CMP of substrates comprising a self-passivating metal, germanium, nickel phosphorous (NiP), or a mixture thereof. In particular, a CMP composition was thought for the polishing of substrates comprising tungsten. In addition, a CMP composition was to be provided which has a long shelf-life and is characterized by high material removal rates (MRRs). Moreover, CMP compositions were contemplated that have a high selectivity between the removal of a substrate comprising a self-passivating metal—in particular tungsten—or germanium on the one hand and any other substrates in a multilevel structure on the other hand. Especially, a CMP composition was to be provided which shows the combination of high MRR of a substrate comprising a self-passivating metal—in particular tungsten—with high selectivity between the removal of a substrate comprising a self-passivating metal—in particular tungsten—on the one hand and any other substrates—in particular silicon oxide—in a multilevel structure on the other hand.

Furthermore, a respective CMP process was to be provided.

Accordingly, it has been found that by polishing a substrate comprising a self-passivating metal, germanium, nickel phosphorus (NiP), or a mixture thereof using a CMP composition comprising

(A) inorganic particles, organic particles, or a mixture thereof,

(B) a heteropolyacid or a salt thereof,

(C) a salt comprising chloride, fluoride, bromide, or a mixture thereof as anion, and

(D) an aqueous medium,

the above-mentioned objects of the invention are achieved.

In addition, the above-mentioned objects of the invention are achieved by a process for the manufacture of a semiconductor device comprising the polishing of a substrate comprising a self-passivating metal, germanium, NiP, or a mixture thereof in the presence of a CMP composition comprising

(A) inorganic particles, organic particles, or a mixture thereof,

(B) a heteropolyacid or a salt thereof,

(C) a salt comprising chloride, fluoride, bromide, or a mixture thereof as anion, and

(D) an aqueous medium.

Moreover, a selected CMP composition (composition S) was found which comprises

(A) inorganic particles, organic particles, or a mixture thereof,

(B) a heteropolyacid or a salt thereof,

(C) a salt comprising chloride, fluoride, bromide, or a mixture thereof as anion, wherein its cation (Z+) is a metal, NH₄+, phosphonium, heterocyclic, homocyclic cation, or a mixture thereof, and

(D) an aqueous medium,

and which fulfills the goal of the invention.

Furthermore, a process meeting the above goals for the manufacture of semiconductor devices comprising the polishing of a substrate in the presence of the selected CMP composition (composition S) was found. Moreover, the use of the selected CMP composition (composition S) and of the above-mentioned process for polishing and/or etching substrates which are used in the semiconductor industry has been found, which fulfills the objects of the invention.

Preferred embodiments are explained in the claims and the specification. It is understood that combinations of preferred embodiments are within the scope of the present invention.

According to the invention, a CMP composition comprising

(A) inorganic particles, organic particles, or a mixture thereof,

(B) a heteropolyacid or a salt thereof,

(C) a salt comprising chloride, fluoride, bromide, or a mixture thereof as anion, and

(D) an aqueous medium,

is used for polishing a substrate comprising a self-passivating metal, germanium, NiP, or a mixture thereof. Preferably, this CMP composition is used for polishing a substrate comprising a self-passivating metal. More preferably, this CMP composition is used for polishing a substrate comprising tungsten. Said substrate can also have other optional components.

According to the invention, a semiconductor device can be manufactured by a process which comprises the polishing of a substrate comprising a self-passivating metal, germanium, NiP, or a mixture thereof in the presence of a CMP composition comprising

(A) inorganic particles, organic particles, or a mixture thereof,

(B) a heteropolyacid or a salt thereof,

(C) a salt comprising chloride, fluoride, bromide, or a mixture thereof as anion, and

(D) an aqueous medium.

Preferably, said process comprises the polishing of a substrate comprising a self-passivating metal. More preferably, it comprises the polishing of a substrate comprising tungsten.

The substrate comprising a self-passivating metal, germanium, NiP, or a mixture thereof can be any substrate used in the semiconductor industry which comprises a self-passivating metal, germanium, NiP, or a mixture thereof. Preferably, said substrate is a substrate which comprises a layer of a self-passivating metal, a germanium layer, a NiP layer, or several different layers. More preferably, said substrate is a substrate which comprises a layer of a self-passivating metal. Most preferably, said substrate is a substrate which comprises a tungsten layer. For example, this substrate is a substrate which comprises a tungsten layer and further layers, such as a nitride and an oxide layer.

Generally, a self-passivating metal is a metal on which surface an oxide layer is formed that prevents the metal from corrosion into its deeper layers. Examples for self-passivating metals are aluminium, chromium, nickel, tungsten, ruthenium, rhodium, palladium, silver, osmium, iridium, platinum, gold, an alloy thereof, or a mixture thereof.

Generally, nickel phosphorus (NiP) is a phosphorus alloy, which usually contains from 5 to 20 wt %, preferably from 9 to 12 wt % (by weight of the alloy in total), of phosphorus and which is conventionally deposited via an auto-catalytic nickel plating process, typically called electroless nickel plating. Specifically in the manufacture of hard disks for hard-disk-drives (memory storage media), said NiP alloys are deposited on an aluminum substrate.

According to the invention, the selected CMP composition of the invention (composition S) can be used for polishing any of said substrates. Composition S can however in principle also be employed for polishing any other substrate which is used in the semi-conductor industry. Other substrates may be for example copper, titanium nitride, or tantalum nitride. Preferably, composition S is used for polishing a substrate which comprises copper, tungsten, germanium, titanium, titanium nitride, ruthenium, aluminum, tantalum, tantalum nitride, platinum, rhodium, NiP, or a mixture thereof. More preferably, composition S is used for polishing a substrate which comprises copper, tungsten, or a mixture thereof. Most preferably, composition S is used for polishing a substrate comprising tungsten.

According to the invention, the CMP composition contains inorganic particles, organic particles, or a mixture thereof (A). A composite particle, i.e. a particle comprising two or more types of particles in such a way that they are mechanically, chemically or in another way bound to each other, is considered as being a mixture of these two types of particles. (A) can be of one type or a mixture of different types of inorganic particles, or (A) can be of one type or a mixture of different types of organic particles, or (A) can be a mixture of one or more types of inorganic particles and one or more types of organic particles.

Generally, particles (A) can be contained in varying amounts. Preferably, the amount of (A) is not more than 10 percent by weight, more preferably not more than 4 percent by weight, most preferably not more than 2 percent by weight, based on the total weight of the corresponding composition. Preferably, the amount of (A) is at least 0.01 percent by weight, more preferably at least 0.07 percent by weight, most preferably at least 0.5 percent by weight, based on the total weight of the corresponding composition.

Generally, particles (A) can be contained in varying particle size distributions. The particle size distributions of (A) can be monomodal or multimodal. In case of multimodal particle size distributions, bimodal is often preferred. In order to have an easily reproducible property profile and easily reproducible conditions during the CMP process of the invention, a monomodal particle size distribution is preferred for (A). It is most preferred for (A) to have a monomodal particle size distribution.

The mean particle size of (A) can vary within a wide range. The mean particle size is the d₅₀ value of the particle size distribution of (A) in the aqueous medium (D) and can be determined using dynamic light scattering techniques. Then, the d₅₀ values are calculated under the assumption that particles are essentially spherical. The width of the mean particle size distribution is the distance (given in units of the x-axis) between the two intersection points, where the particle size distribution curve crosses the 50% height of the relative particle counts, wherein the height of the maximal particle counts is standardized as 100% height.

Preferably, the mean particle size of (A) is in the range of from 5 to 500 nm, more preferably in the range of from 5 to 250 nm, most preferably in the range of from 20 to 150 nm, and in particular in the range of from 90 to 130 nm, as measured with dynamic light scattering techniques using instruments such as High Performance Particle Sizer (HPPS) from Malvern Instruments, Ltd. or Horiba LB550.

The particles (A) can be of various shapes. Thereby, (A) may be of one or essentially only one type of shape. However, it is also possible that (A) have different shapes. For instance, two types of differently shaped particles (A) may be present. For example, (A) can have the shape of cubes, cubes with chamfered edges, octahedrons, icosahedrons, nodules or spheres with or without protrusions or indentations. Preferably, they are spherical with no or only very few protrusions or indentations. This shape, as a rule, is preferred because this shape usually assures the least amount of defects on the polished substrates such as scratches.

The chemical nature of particles (A) is not particularly limited. (A) may be of the same chemical nature or a mixture of particles of different chemical nature. As a rule, particles (A) of the same chemical nature are preferred. Generally, (A) can be
inorganic particles such as a metal, a metal oxide or carbide, including a metalloid, a metalloid oxide or carbide, or
organic particles such as polymer particles,
a mixture of inorganic and organic particles.

Particles (A) are preferably inorganic particles. Among them, oxides and carbides of metals or metalloids are preferred. More preferably, particles (A) are alumina, ceria, copper oxide, iron oxide, nickel oxide, manganese oxide, silica, silicon nitride, silicon carbide, tin oxide, titania, titanium carbide, tungsten oxide, yttrium oxide, zirconia, or mixtures thereof. Most preferably, particles (A) are alumina, ceria, silica, titania, zirconia, or mixtures thereof. In particular, (A) are silica. For example, (A) are colloidal silica. Generally, colloidal silica are fine amorphous, nonporous, and typically spherical silica particles.

In another embodiment in which (A) are organic particles, or a mixture of inorganic and organic particles, polymer particles are preferred. Polymer particles can be homo- or copolymers. The latter may for example be block-copolymers, or statistical copolymers. The homo- or copolymers may have various structures, for instance linear, branched, comb-like, dendrimeric, entangled or cross-linked. The polymer particles may be obtained according to the anionic, cationic, controlled radical, free radical mechanism and by the process of suspension or emulsion polymerisation. Preferably, the polymer particles are at least one of the polystyrenes, polyesters, alkyd resins, polyurethanes, polylactones, polycarbonates, poylacrylates, polymethacrylates, polyethers, poly(N-alkylacrylamide)s, poly(methyl vinyl ether)s, or copolymers comprising at least one of vinylaromatic compounds, acrylates, methacrylates, maleic anhydride acrylamides, methacrylamides, acrylic acid, or methacrylic acid as monomeric units, or mixtures thereof. Among them, polymer particles with a cross-linked structure are preferred.

According to the invention, the CMP composition contains a heteropolyacid or salt thereof (B). (B) can be of one type or a mixture of different types of heteropolyacids or salts thereof.

Generally, the heteropolyacid or a salt thereof (B) can be contained in varying amounts. Preferably, the amount of (B) is from 0.01 to 15 percent by weight, more preferably from 0.1 to 10 percent by weight, most preferably from 0.2 to 5 percent by weight, for example from 0.4 to 2.5 percent by weight, based on the total weight of the corresponding composition.

Generally, the chemical composition of the heteropolyacid or a salt thereof (B) can vary to a large degree. As a heteropolyacid according to the invention, any inorganic acid comprising hydrogen, oxygen and at least two different main atoms can be used. As the first main atom forming the heteropolyacid, Cu, Be, B, Al, C, Si, Ge, Sn, Ti, Zr, Ce, Th, N, P, As, Sb, V, Nb, Ta, Cr, Mo, W, U, S, Se, Te, Mn, I, Fe, Co, Ni, Rh, Os, Ir and Pt can be selected. Among them, V, Mo, W are preferred as the first main atom. As the second main atom forming the heteropolyacid, which is different from the above-mentioned first main atom, Be, B, Al, C, Si, Ge, Sn, Ti, Zr, Ce, Th, N, P, As, Sb, V, Nb, Ta, Cr, Mo, W, U, S, Se, Te, Mn, I, Fe, Co, Ni, Rh, Os, Ir and Pt can be selected. Among them, As, I, P, Se, Si, Te are preferred as the second main atom.

The heteropolyacid or a salt thereof (B) is preferably a heteropolyacid comprising at least one of the elements V, Mo, W, or a salt thereof. More preferably, (B) is a heteropolyacid comprising vanadium and/or molybdenum, or a salt thereof. Most preferably, (B) is a phosphovanadiomolybdic acid or a salt thereof. For example, (B) is a heteropolyacid of the formula

HₐX_{b}P₃Mo_{y}V_{z}O_{c}
wherein X=any cation other than H
   8≦y≦18
   8≦z≦14
   56≦c≦105
   a+b=2c-6y-5(3+z)
   b≧0 and a>0
      or a salt thereof.

Generally, the heteropolyacid or a salt thereof (B) can be either an acid, or a salt, in which one or more protons of the heteropolyacid are replaced by one or more cations (X+). Preferably, (B) is a salt in which one or more protons of the heteropolyacid are replaced by one or more cations (X+). More preferably, (B) is a salt in which two to twelve protons of the heteropolyacid are replaced by the corresponding number of cations (X+). Most preferably, (B) is a salt in which three to nine protons of the heteropolyacid are replaced by the corresponding number of cations (X+). For example, (B) is a salt in which three to nine protons of the heteropolyacid are replaced by the corresponding number of NH₄+ cations.

In case (B) is a salt of a heteropolyacid, the cation or cations (X+) comprised in (B) can be of various chemical natures. (X+) may be of the same chemical nature or a mixture of cations of different chemical nature. As a rule, cations (X+) of the same chemical nature are preferred. Generally, (X+) can be any cation. Preferably, (X+) is a metal cation, an inorganic or organic ammonium cation, a phosphonium cation, a heterocyclic cation, or an homocyclic cation. More preferably, (X+) is a metal cation, an inorganic or organic ammonium cation. Most preferably, (X+) is a alkali metal cation, an earth alkali metal cation, an NH₄+ cation, or a mono-, di-, tri- or tetraalkylammonium cation. For example, (X+) is an NH₄+ cation.

According to the invention, the CMP composition contains a salt comprising chloride, fluoride, bromide, or a mixture thereof as anion (C). (C) can be of one type or a mixture of different types of salts comprising chloride, fluoride, bromide, or a mixture thereof as anion.

Generally, the salt comprising chloride, fluoride, bromide, or a mixture thereof as anion (C) can be contained in varying amounts. Preferably, the amount of (C) is from 0.01 to 20 percent by weight, more preferably from 0.1 to 10 percent by weight, most preferably from 0.2 to 5 percent by weight, for example from 0.4 to 2.5 percent by weight, based on the total weight of the corresponding composition with regard to the weight of the chloride, fluoride, and/or bromide anions alone.

Generally, the salt comprising chloride, fluoride, bromide, or a mixture thereof as anion (C) can be any salt comprising chloride, fluoride, bromide, or a mixture thereof as anion. (C) can be a salt, in which the anions are a mixture of chloride, and/or fluoride, and/or bromide anions. (C) may be of the same chemical nature or a mixture of salts (C) of different chemical nature. As a rule, a salt (C) of the same chemical nature is preferred. (C) can be a salt in which further anions, other than chloride, fluoride and bromide, exist. Preferably, (C) is a chloride-containing salt. More preferably, (C) is a chloride-containing salt, in which the anions are exclusively chloride anions.

Generally, the cation or cations (Z+) comprised in the salt (C) can be of various chemical natures. (Z+) may be of the same chemical nature or a mixture of cations of different chemical nature. As a rule, cations (Z+) of the same chemical nature are preferred.

In the embodiment in which the CMP composition is used for polishing a substrate comprising a self-passivating metal, germanium, NiP, or a mixture thereof, (Z+) can be any cation. Preferably, (Z+) is/are metal cation/s, inorganic, or organic ammonium cation/s, phosphonium, heterocyclic, or homocyclic cation/s. More preferably, (Z+) is/are metal cation/s, inorganic, or organic ammonium cation/s. Most preferably, (Z+) is/are alkali metal, earth alkali metal, NH₄+, or mono-, di-, tri- or tetraalkylammonium cation/s. For example, (Z+) is/are Na+, K+, or NH₄+ cation/s.

According to the invention, the selected CMP composition (composition S) contains a salt (C) wherein the cation/s (Z+) comprised in the salt (C) is/are metal, NH₄+, phosphonium, heterocyclic, or homocyclic cation/s, or a mixture thereof. More preferably, (Z+) is/are alkali metal, earth alkali metal, NH₄+, phosphonium, heterocyclic, or homocyclic cation/s. Most preferably, (Z+) is/are alkali metal, earth alkali metal, or NH₄+ cation/s. For example, (Z+) is/are Na+, K+, or NH₄+ cation/s.

A heterocyclic cation is a cationic cyclic compound with two different chemical elements as ring members atoms. A homocyclic cation is a cationic cyclic compound with one chemical element as ring members atoms.

According to the invention, the CMP composition contains an aqueous medium (D). (D) can be of one type or a mixture of different types of aqueous media.

In general, the aqueous medium (D) can be any medium which contains water. Preferably, the aqueous medium (D) is a mixture of water and an organic solvent miscible with water (e.g. an alcohol, preferably a C₁ to C₃ alcohol, or an alkylene glycol derivative). More preferably, the aqueous medium (D) is water. Most preferably, aqueous medium (D) is de-ionized water.

If the amounts of the components other than (D) are in total x % by weight of the CMP composition, then the amount of the component (D) is (100-x) % by weight of the CMP composition.

The properties of the CMP compositions used or according to the invention respectively, such as stability and polishing performance, may depend on the pH of the corresponding composition. Preferably, the pH value of the compositions used or according to the invention respectively is in the range of from 0 to 5, more preferably from 0 to 3.5, and most preferably from 0.5 to 2.5.

The CMP compositions used or according to the invention respectively may also contain, if necessary, various other additives, including but not limited to pH adjusting agents, stabilizers, surfactants, corrosion inhibitors. Said other additives are for instance those commonly employed in CMP compositions and thus known to the person skilled in the art. Such addition can, additionally, stabilize the dispersion, or improve the polishing performance, or the selectivity between different layers.

As an additive, any organic compound having at least one carboxyl (—COOH) or carboxylate (—COO⁻) group may be used. Generally, this organic compound is soluble in the aqueous medium (D). Preferably, an amino acid, or a carboxylic acid having at least two carboxyl groups is used as an additive. More preferably, proline, lysine, iso-leucine, arginine, cysteine, or malonic acid is used as an additive. Most preferably, proline, or arginine is used as an additive.

If present, said additive can be contained in varying amounts. Preferably, the amount of said additive is not more than 10 percent by weight, more preferably not more than 5 percent by weight, most preferably not more than 2 percent by weight, for example not more than 1 percent by weight, based on the total weight of the corresponding composition. Preferably, the amount of said additive is at least 0.001 percent by weight, more preferably at least 0.005 percent by weight, most preferably at least 0.02 percent by weight, for example at least 0.05 percent by weight, based on the total weight of the corresponding composition.

According to one embodiment, the CMP composition which is used for polishing a substrate comprising a self-passivating metal, germanium, NiP, or a mixture thereof, comprises
(A) inorganic particles, organic particles, or a mixture thereof,
(B) a phosphotungstic acid, a silicotungstic acid, a phosphomolybdic acid, a silicomolybdic acid, a phosphotungstomolybdic acid, a silicotungstomolybdic acid, a phosphovanadiomolybdic acid, a silicovanadiomolybdic acid, a phosphovanadiotungstic acid, or a silicovanadiotungstic acid, or a salt thereof, in an amount of from 0.1% to 5% by weight of the CMP composition,
(C) a salt comprising chloride, fluoride, bromide, or a mixture thereof as anion in an amount of from 0.1% to 5% by weight of the CMP composition with regard to the weight of the chloride, fluoride, and/or bromide anions alone, and
(D) water.

According to a further embodiment, the CMP composition which is used for polishing a substrate comprising a self-passivating metal, germanium, NiP, or a mixture thereof, comprises
(A) polymer particles,
(B) a heteropolyacid, or a salt thereof, in an amount of from 0.1% to 5% by weight of the CMP composition,
(C) a salt comprising chloride, fluoride, bromide, or a mixture thereof as anion in an amount of from 0.1% to 5% by weight of the CMP composition with regard to the weight of the chloride, fluoride, and/or bromide anions alone, and
(D) water.

According to a further embodiment, the CMP composition which is used for polishing a substrate comprising a self-passivating metal, germanium, NiP, or a mixture thereof, comprises
(A) inorganic particles, organic particles, or a mixture thereof,
(B) a phosphovanadiomolybdic acid or a salt thereof, in an amount of from 0.1% to 5% by weight of the CMP composition,
(C) a salt comprising chloride, fluoride, bromide, or a mixture thereof as anion in an amount of from 0.1% to 5% by weight of the CMP composition with regard to the weight of the chloride, fluoride, and/or bromide anions alone, and
(D) water.

According to a further embodiment, the CMP composition which is used for polishing a substrate comprising a self-passivating metal, germanium, NiP, or a mixture thereof, comprises
(A) alumina, ceria, silica, titania, zirconia, or a mixture thereof,
(B) a phosphovanadiomolybdic acid or a salt thereof, in an amount of from 0.1% to 5% by weight of the CMP composition,
(C) a salt comprising chloride, fluoride, bromide, or a mixture thereof as anion in an amount of from 0.1% to 5% by weight of the CMP composition with regard to the weight of the chloride, fluoride, and/or bromide anions alone, and
(D) water, and
(E) an organic compound having at least one carboxyl (—COOH) or carboxylate (—COO⁻) group.

According to a further embodiment, the CMP composition which is used for polishing a substrate comprising tungsten, comprises
(A) silica,
(B) a heteropolyacid of the formula

HₐX_{b}P₃Mo_{y}V_{z}O_{c}
wherein X=any cation other than H
   8≦y≦18
   8≦z≦14
   56≦c≦105
   a+b=2c-6y-5(3+z)
   b≧0 and a>0
or a salt thereof, in an amount of from 0.1% to 5% by weight of the CMP composition,
(C) a chloride-containing salt in an amount of from 0.1% to 5% by weight of the CMP composition with regard to the weight of the chloride anions alone, and
(D) water.

According to a further embodiment, the selected CMP composition (composition S), which is used for polishing any substrate used in the semiconductor industry, comprises,
(A) alumina, ceria, silica, titania, zirconia, or a mixture thereof,
(B) a phosphovanadiomolybdic acid or a salt thereof,
(C) a chloride-containing salt, wherein its cation (Z+) is an alkali metal, earth alkali metal, NH₄+ cation, or a mixture thereof, and
(D) water.

According to a further embodiment, the selected CMP composition (composition S), which is used for polishing any substrate used in the semiconductor industry, comprises
(A) inorganic particles, organic particles, or a mixture thereof,
(B) a phosphotungstic acid, a silicotungstic acid, a phosphomolybdic acid, a silicomolybdic acid, a phosphotungstomolybdic acid, a silicotungstomolybdic acid, a phosphovanadiomolybdic acid, a silicovanadiomolybdic acid, a phosphovanadiotungstic acid, or a silicovanadiotungstic acid, or a salt thereof, in an amount of from 0.1% to 5% by weight of the CMP composition,
(C) a salt comprising chloride, fluoride, bromide, or a mixture thereof as anion in an amount of from 0.1% to 5% by weight of the CMP composition with regard to the weight of the chloride, fluoride, and/or bromide anions alone, wherein its cation (Z+) is a metal, NH₄+, phosphonium, heterocyclic, or homocyclic cation, or a mixture thereof, and
(D) water.

According to a further embodiment, the selected CMP composition (composition S), which is used for polishing any substrate used in the semiconductor industry, comprises
(A) polymer particles,
(B) a heteropolyacid, or a salt thereof, in an amount of from 0.1% to 5% by weight of the CMP composition,
(C) a salt comprising chloride, fluoride, bromide, or a mixture thereof as anion in an amount of from 0.1% to 5% by weight of the CMP composition with regard to the weight of the chloride, fluoride, and/or bromide anions alone, wherein its cation (Z+) is a metal, NH₄+, phosphonium, heterocyclic, or homocyclic cation, or a mixture thereof, and
(D) water.

According to a further embodiment, the selected CMP composition (composition S), which is used for polishing any substrate used in the semiconductor industry, comprises
(A) inorganic particles, organic particles, or a mixture thereof,
(B) a phosphovanadiomolybdic acid or a salt thereof, in an amount of from 0.1% to 5% by weight of the CMP composition,
(C) a salt comprising chloride, fluoride, bromide, or a mixture thereof as anion in an amount of from 0.1% to 5% by weight of the CMP composition with regard to the weight of the chloride, fluoride, and/or bromide anions alone, wherein its cation (Z+) is a metal, NH₄+, phosphonium, heterocyclic, or homocyclic cation, or a mixture thereof, and
(D) water.

According to further embodiment, the selected CMP composition (composition S), which is used for polishing any substrate used in the semiconductor industry, comprises
(A) alumina, ceria, silica, titania, zirconia, or a mixture thereof,
(B) a phosphovanadiomolybdic acid or a salt thereof, in an amount of from 0.1% to 5% by weight of the CMP composition
(C) a chloride-containing salt in an amount of from 0.1% to 5% by weight of the CMP composition with regard to the weight of the chloride anions alone, wherein its cation (Z+) is an alkali metal, earth alkali metal, NH₄+ cation, or a mixture thereof,
(D) water, and
(E) an organic compound having at least one carboxyl (—COOH) or carboxylate (—COO⁻) group.

According to a further embodiment, the selected CMP composition (composition S), which is used for polishing any substrate used in the semiconductor industry, comprises
(A) silica,
(B) a heteropolyacid of the formula

HₐX_{b}P₃Mo_{y}V_{z}O_{c}
wherein X=any cation other than H
   8≦y≦18
   8≦z≦14
   56≦c≦105
   a+b=2c-6y-5(3+z)
b≧0 and a>0
   or a salt thereof, in an amount of from 0.1% to 5% by weight of the CMP composition,
(C) a chloride-containing salt in an amount of from 0.1% to 5% by weight of the CMP composition with regard to the weight of the chloride anions alone, wherein its cation (Z+) is an alkali metal, earth alkali metal, NH₄+ cation, or a mixture thereof, and
(D) water.

Processes for preparing CMP compositions are generally known. These processes may be applied to the preparation of the CMP composition of the invention. This can be carried out by dispersing or dissolving the above-described components (A), (B) and (C) in the aqueous medium (D), preferably water, and optionally by adjusting the pH value through adding an acid, a base, a buffer or an pH adjusting agent. For this purpose the customary and standard mixing processes and mixing apparatuses such as agitated vessels, high shear impellers, ultrasonic mixers, homogenizer nozzles or counterflow mixers, can be used.

The CMP composition of the invention is preferably prepared by dispersing the inorganic particles, organic particles, or a mixture thereof (A), adding the heteropolyacid or a salt thereof (B) either in form of a liquid solution or by dissolving it as a solid (B), and the salt comprising chloride, fluoride, bromide, or a mixture thereof as anion (C) as a liquid solution thereof in the aqueous medium (D). For example, the abrasives can be added as a predispersed masterbatch dispersion and/or as silica powder. For dispersing, methods such as high shear mixing can be for example used. The soluble components, that are (B) and (C), can be dissolved using standard mixing procedures.

The polishing process is generally known and can be carried out with the processes and the equipment under the conditions customarily used for the CMP in the fabrication of wafers with integrated circuits. There is no restriction on the equipment with which the polishing process can be carried out.

As known in the art, typical equipment for the CMP process consists of a rotating platen which is covered with a polishing pad. Also orbital polishers have been used. The wafer is mounted on a carrier or chuck. The side of the wafer being processed is facing the polishing pad (single side polishing process). A retaining ring secures the wafer in the horizontal position (as an example for a CMP polisher see U.S. Pat. No. 6,050,885).

Below the carrier, the larger diameter platen is also generally horizontally positioned and presents a surface parallel to that of the wafer to be polished. The polishing pad on the platen contacts the wafer surface during the planarization process.

To produce material loss, the wafer is pressed onto the polishing pad. Both the carrier and the platen are usually caused to rotate around their respective shafts extending perpendicular from the carrier and the platen. The rotating carrier shaft may remain fixed in position relative to the rotating platen or may oscillate horizontally relative to the platen. The direction of rotation of the carrier is typically, though not necessarily, the same as that of the platen. The speeds of rotation for the carrier and the platen are generally, though not necessarily, set at different values. During the CMP process of the invention the CMP composition of the invention is usually applied onto the polishing pad as a continuous stream or in dropwise fashion. Customarily, the temperature of the platen is set at temperatures of from 10 to 70° C.

The load on the wafer can be applied by a flat plate made of steel for example (hard platen design, see for instance figures in U.S. Pat. No. 4,954,142 or U.S. Pat. No. 6,093,091), covered with a soft pad that is often called backing film. If more advanced equipment is being used a flexible membrane that is loaded with air or nitrogen pressure (membrane carriers, for example see U.S. Pat. No. 6,767,276) presses the wafer onto the pad. Such a membrane carrier is preferred for low down force processes when a hard polishing pad is used, because the down pressure distribution on the wafer is more uniform compared to that of a carrier with a hard platen design. Carriers with the option to control the pressure distribution on the wafer may also be used according to the invention. They are usually designed with a number of different chambers that can be loaded independently from each other (zone carriers, see for an example U.S. Pat. No. 7,207,871).

For further details reference is made to WO 2004/063301 A1, in particular page 16, paragraph [0036] to page 18, paragraph [0040] in conjunction with the FIG. 2.

By way of the CMP process of the invention and/or using the selected CMP composition of the invention (composition S), wafers with integrated circuits comprising a metal layer can be obtained with an excellent surface finish.

The CMP composition can be used according to the invention and the selected CMP composition of the invention (composition S) can be used in the CMP process as ready-to-use slurry; it has a long shelf-life and shows a stable particle size distribution over long time. Thus it is easy to handle and to store. It shows an excellent polishing performance, particularly with regard to material removal rate (MRR) and selectivity. For example, a high selectivity between a self-passivating metal or germanium on the one hand and silicon oxide on the other hand can be obtained in combination with high MRRs of the self-passivating metal when a substrate comprising tungsten or germanium and silicon oxide layers is polished. Since the amounts of its components are held down to a minimum, the CMP compositions used or according to the invention respectively can be used in a cost-effective way.

### EXAMPLES AND COMPARATIVE EXAMPLES

Analytical Methods

The elementary analyses of Mo, P and V were measured by ICP-OES (inductively coupled plasma optical emission spectrometry).

All formulas representing the heteropolyacid or a salt thereof were normalized to P₃.

The pH value is measured with a pH electrode (Schott, blue line, pH 0-14/−5 . . . 100° C./3 mol/L sodium chloride).

Inorganic Particles (A′)

Colloidal silica particles having a mean particle size (d50) of 80 nm—as measured using dynamic light scattering techniques—were used as inorganic particles (A′) in the Examples 1-9 (see Table 1). In other examples, colloidal silica as specified in Table 1 were used and were of NexSil™ (Nyacol) and Silicas Silco (Evonik) type. NexSil™ 125K (Nyacol) are potassium-stabilized colloidal silica having a typical particle size of 85 nm and a typical surface area of 35 m²/g. NexSil™ 85K (Nyacol) are potassium-stabilized colloidal silica having a typical particle size of 50 nm and a typical surface area of 55 m²/g. NexSil™ 20K (Nyacol) are potassium-stabilized colloidal silica having a typical particle size of 20 nm and a typical surface area of 135 m²/g. Evonik Silicas Silco EM-5530K are colloidal silica having an average particle size of 55 nm and a typical surface area of 80 m²/g, which are stabilized with potassium hydroxide. Evonik Silicas Silco EM-7530K are colloidal silica having an average particle size of 75 nm and a typical surface area of 70 m²/g, which are stabilized with potassium hydroxide.

Synthesis of the Heteropolyacid or a Salt Thereof (B′)

### Synthesis Example 1

### Synthesis of H_{12.4}(NH₄)_{4.6}P₃Mo₁₆V₁₂O₉₄

To 4000 ml water and 661.2 g aqueous H₂O₂-solution (30%), 181.88 g of V₂O₅ were added at 2° C. within 1 minute while continuous stirring. After 30 minutes the mixture was warmed up to 18° C. and phosphoric acid (69.17 g, 85%) was added. After stirring for 20 minutes, the reaction mixture was heated up to 40° C. and 461.06 g MoO₃ were added. Then, the mixture was heated to 84° C. for 45 minutes. Then, the solution was cooled to room temperature and filtered.

61.30 g (NH₄)₂HPO₄ were dissolved in 464 ml water. The filtered heteropolyacid solution was reheated to 70° C. and the (NH₄)₂HPO₄ solution was added within one hour. After cooling to room temperature the product solution was filtered once again. Mo 5.4 g/100 g, V 2.1 g/100 g, P 0.57/100 g, N<0,5 g/100 g pH 1.27

### Synthesis Example 2

### Synthesis of H_{9.25}(NH₄)_{7.75}P₃Mo₁₆V₁₂O₉₄

To 20 l deionized water and 3306.2 g aqueous H₂O₂-solution (30%), 1091.4 g of V₂O₅ were added at 1° C. within 1 minute while continuous stirring. The mixture was warmed up to 16° C. and stirred 25 minutes at this temperature. Phosphoric acid (345.8 g, 85%) was added. After stirring for 20 minutes, the reaction mixture was heated up to 40° C. and 2305.4 g MoO₃ were added in one portion. Then, the mixture was to 80° C. for 45 minutes. The solution was cooled to room temperature and filtered.

610.4 g NH₄HCO₃ were dissolved in 464 ml water. The filtered heteropolyacid solution was reheated to 70° C. and the NH₄HCO₃ solution was added within 6.5 hours. After 1 hour at 70° C. the mixture was cooled to room temperature and filtered once again. Mo 5.6 g/100 g, V 2.1 g/100 g, P 0.33/100 g, N 0.5 g/100 g

### Examples 1-13

### (Compositions of the Invention) and Comparative Examples C1-C2 (Comparative Composition)

A dispersion containing inorganic particles (A′), the heteropolyacid or a salt thereof (B′), a chloride-containing salt (C′) and optionally the additive in water was prepared. This composition forms the basis for the CMP compositions of the examples 1-13, as specified in Table 1. The synthesis of the heteropolyacids used in the compositions are described in synthesis example 1 (H_{12.4}(NH₄)_{4.6}P₃Mo₁₆V₁₂O₉₄) and synthesis example 2 (H_{9.25}(NH₄)_{7.75}P₃Mo₁₆V₁₂O₉₄). As a reference, dispersions in de-ionized water which do not comprise the chloride-containing salt (C′) was used (comparative examples C1-C2). For all examples, the weight percentages (wt %), that are the weight of the corresponding components in percent of the total weight of the CMP composition, are given in Table 1. The synthetically optimized heteropolyacid structures preferentially gave a pH value of 1.5-3 when dissolved as 1.5% solution in deionized water. For all these examples, the pH was adjusted to 2.0 with HNO₃ if the heteropolyacid solution yielded a pH above 2, to assure comparable acidic conditions.

Unless otherwise mentioned, such as for the heteropolyacids, all chemicals listed in this publication were used without purification from commercial chemical suppliers.

For example, KCl was ordered from Sigma Aldrich (12636) and used without any further purification, Arginine was odered from Roth (3144-1) and used without any further purification, L-Proline was ordered from ABCR (AB110535) and used without any further purification.

General Procedure for the CMP Experiments

First trends of formulations were evaluated on 2 inch tungsten disc level using Bühler table polishers. For further evaluation and confirmation a 200 mm Strasbaugh 6EC polisher was used (polishing time was 60 s).

For the evaluation on benchtop following parameters were chosen:

Powerpro 5000 Bühler. DF=40 N, Table speed 150 rpm, Platen speed 150 rpm, slurry flow 200 ml/min, 20 s conditioning, 1 min polishing time, IC1000 pad, diamond conditioner (3M).

The pad is conditioned by several sweeps, before a new type of CMP composition is used for CMP. For the determination of removal rates at least 3 wafers are polished and the data obtained from these experiments are averaged.

The CMP composition is stirred in the local supply station.

The material removal rates (MRR) for 2 inch tungsten discs polished by the CMP composition are determined by difference of weight before and after CMP, using a Sartorius LA310 S scale. The difference of weight can be converted into the difference of film thickness since the density (19.25 g/cm3 for tungsten) and the surface area of the polished material are known. Dividing the difference of film thickness by the polishing time provides the values of the material removal rate.

For determination of the selectivity towards oxide, 2 inch TEOS wafers were polished and/or glass bulk disks were used. The RR of the SiO2 could then be determined in a similar manner as the tungsten metal. For determination of the TiN material removal rate (MRR), 2 inch TiN wafers were used.

Data for the polishing performance of the CMP compositions of the examples 1-13 and of the comparative examples C1-02 are given in the Table 1:

TABLE 1
Compositions of the examples 1-13 and of the comparative examples C1-C2
(Aqueous medium is water), material removal rates (MRR) and selectivities
in the CMP process using these compositions

| | | | Chloride- | | | |
|---|---|---|---|---|---|---|
| | Inorganic | Heteropolyacid | containing | | MRR | Selectivity |
| | Particles | or a salt thereof | salt | | (W) | MRR(W)/ |
| Compositions | (A′) | (B′) | (C′) | Additive | [Å/min] | MRR(SiO₂) |
| Example 1 | Colloidal | H_{12.4}(NH₄)_{4.6}P₃ | KCl | Proline | 2655 | 25:1 |
| | silica | Mo₁₆V₁₂O₉₄ | 2 wt % | 0.5 wt % | | |
| | 1.5 wt % | 1.5 wt % | | | | |
| Example 2 | Colloidal | H_{12.4}(NH₄)_{4.6}P₃ | KCl | Proline | 2601 | 14:1 |
| | silica | Mo₁₆V₁₂O₉₄ | 2 wt % | 0.1 wt % | | |
| | 1.5 wt % | 1.5 wt % | | | | |
| Example 3 | Colloidal | H_{12.4}(NH₄)_{4.6}P₃ | KCl | Arginine | 2436 | 10.6:1 |
| | silica | Mo₁₆V₁₂O₉₄ | 2 wt % | 0.05 wt % | | |
| | 1.5 wt % | 1.5 wt % | | | | |
| Example 4 | Colloidal | H_{12.4}(NH₄)_{4.6}P₃ | KCl | Malonic | 2610 | 15:1 |
| | silica | Mo₁₆V₁₂O₉₄ | 2 wt % | acid | | |
| | 1.5 wt % | 1.5 wt % | | 0.05 wt % | | |
| Example 5 | Colloidal | H_{12.4}(NH₄)_{4.6}P₃ | KCl | | 2813 | 6:1 |
| | silica | Mo₁₆V₁₂O₉₄ | 2 wt % | | | |
| | 1.5 wt % | 1.5 wt % | | | | |
| Example 6 | Colloidal | H_{12.4}(NH₄)_{4.6}P₃ | KCl | | 1704 | 6:1 |
| | silica | Mo₁₆V₁₂O₉₄ | 0.5 wt % | | | |
| | 1.5 wt % | 1.5 wt % | | | | |
| Example 7 | Colloidal | H_{12.4}(NH₄)_{4.6}P₃ | NH₄Cl | | 1252 | |
| | silica | Mo₁₆V₁₂O₉₄ | 0.5 wt % | | | |
| | 1.0 wt % | 0.5 wt % | | | | |
| Example 8 | Colloidal | H_{12.4}(NH₄)_{4.6}P₃ | KBr | | 1120 | |
| | silica | Mo₁₆V₁₂O₉₄ | 0.5 wt % | | | |
| | 1.0 wt % | 0.5 wt % | | | | |
| Example 9 | Nyacol | H_{9.25}(NH₄)_{7.75}P₃ | KCl | | 2813 | 6:1 |
| | NexSil ™ | Mo₁₆V₁₂O₉₄ | 2 wt % | | | |
| | 125K | 1.5 wt % | | | | |
| | 1.5 wt % | | | | | |
| Example | Nyacol | H_{9.25}(NH₄)_{7.75}P₃ | KCl | | 2275 | 5:1 |
| 10 | NexSil ™ | Mo₁₆V₁₂O₉₄ | 2 wt % | | | |
| | 85K | 1.5 wt % | | | | |
| | 1.5 wt % | | | | | |
| Example | Nyacol | H_{9.25}(NH₄)_{7.75}P₃ | KCl | | 2416 | 8:1 |
| 11 | NexSil ™ | Mo₁₆V₁₂O₉₄ | 2 wt % | | | |
| | 20K | 1.5 wt % | | | | |
| | 1.5 wt % | | | | | |
| Example | Evonik | H_{9.25}(NH₄)_{7.75}P₃ | KCl | | 2046 | |
| 12 | Silicas Silco | Mo₁₆V₁₂O₉₄ | 2 wt % | | | |
| | Electronic | 1.5 wt % | | | | |
| | Materials | | | | | |
| | EM-7530K | | | | | |
| | 1.5 wt % | | | | | |
| Example | Evonik | H_{9.25}(NH₄)_{7.75}P₃ | KCl | | 2275 | |
| 13 | Silicas Silco | Mo₁₆V₁₂O₉₄ | 2 wt % | | | |
| | Electronic | 1.5 wt % | | | | |
| | Materials | | | | | |
| | EM-5530K | | | | | |
| | 1.5 wt % | | | | | |
| Comparative | Colloidal | H_{12.4}(NH₄)_{4.6}P₃ | | | 1400 | 6:1 |
| Example | silica | Mo₁₆V₁₂O₉₄ | | | | |
| C1 | 1.5 wt % | 1.5 wt % | | | | |
| Comparative | Colloidal | H_{12.4}(NH₄)_{4.6}P₃ | | | 970 | |
| Example | silica | Mo₁₆V₁₂O₉₄ | | | | |
| C2 | 1.0 wt % | 0.5 wt % | | | | |

These examples of the CMP compositions of the invention improve the polishing performance.

1. A process for polishing a substrate, the process comprising:
applying a chemical mechanical polishing (CMP) composition,
wherein the CMP composition comprises:
(A) inorganic particles, organic particles, or a mixture thereof,
(B) a heteropolyacid or a salt thereof,
(C) a salt comprising chloride, fluoride, bromide, or a mixture thereof as an anion, and
(D) an aqueous medium, and
the substrate comprises a self-passivating metal, germanium, nickel phosphorous (NiP), or a mixture thereof.

2. The process for polishing a substrate to claim 1:
wherein the substrate comprises tungsten.

3. A process for manufacturing a semiconductor device, comprising:
polishing a substrate comprising a self-passivating metal, germanium, NiP, or a mixture thereof in the presence of a CMP composition comprising:
(A) inorganic particles, organic particles, or a mixture thereof,
(B) a heteropolyacid or a salt thereof,
(C) a salt comprising chloride, fluoride, bromide, or a mixture thereof as an anion, and
(D) an aqueous medium.

4. The process according to claim 3, comprising polishing a substrate comprising tungsten.

5. A CMP composition, comprising:
(A) inorganic particles, organic particles, or a mixture thereof,
(B) a heteropolyacid or a salt thereof,
(C) a salt comprising chloride, fluoride, bromide, or a mixture thereof as an anion, wherein its cation (Z⁺) is a metal, NH₄⁺, phosphonium, heterocyclic, homocyclic cation, or a mixture thereof, and
(D) an aqueous medium.

6. The CMP composition according to claim 5, wherein (A) are inorganic particles.

7. The CMP composition according to claim 5, wherein (C) is a chloride-containing salt.

8. The CMP composition according to claim 5,
wherein the cation (Z⁺) is an alkali metal, earth alkali metal, NH₄⁺ cation, or a mixture thereof.

9. The CMP composition according to claim 5, wherein (B) comprises at least one of the elements selected from the group consisting of vanadium, molybdenum, and tungsten.

10. The CMP composition according to claim 5,
wherein (B) is a phosphovanadiomolybdic acid or a salt thereof.

11. The CMP composition according to claim 5,
wherein a concentration of the salt (C) is from 0.1% to 10% by weight of the CMP composition with regard to a weight of the chloride, fluoride, or bromide anions alone.

12. The CMP composition according to claim 5,
wherein
(A) is alumina, ceria, silica, titania, zirconia, or a mixture thereof,
(B) is a phosphovanadiomolybdic acid or a salt thereof,
(C) is a chloride-containing salt, and
(D) is water,
wherein the cation (Z⁺) is a alkali metal, earth alkali metal, NH₄⁺, or a combination thereof.

13. The CMP composition according to claim 5, further comprising an organic compound having a carboxyl (—COOH) or a carboxylate (—COO⁻) group.

14. A process for manufacturing semiconductor devices, comprising:
polishing a substrate in the presence of the CMP composition according to claim 5.

15. A process for polishing, etching, or both polishing and etching a substrate, the process comprising:
contacting the CMP composition according to claim 5
wherein the substrate is suitable for semiconductor industry.
